(19) United States
(12) Patent Application Publication
(10) Pub. No.: US 2026/0121371 A1
(43) Pub. Date: Apr. 30, 2026

(54) TUNABLE OSCILLATOR WITH LOW PHASE NOISE

(71) Applicant: BAE Systems Information and Electronic Systems Integration Inc., Nashua, NH (US)

(72) Inventors: Zakary N. Burkley, Amherst, NH (US); Mackenzie A. Van Camp, Lowell, MA (US); Steven E. Turner, Nashua, NH (US); Shailendra Srinivas, Nashua, NH (US); Thien An Nguyen, Austin, TX (US); John Jost, Chardonne (CH); Leif Johansson, Santa Barbara, CA (US)

(21) Appl. No.: 18/933,777

(22) Filed: Oct. 31, 2024

(51) Int. Cl. H01S 5/00; G02B 6/42; H01S 5/062; H03D 7/12; H03K 5/1252

(52) U.S. Cl. CPC H01S 5/0085; G02B 6/4203; G02B 6/4271; H01S 5/062; H03D 7/12; H03K 5/1252

(57) ABSTRACT

In one example, an RF oscillator system includes a laser source configured to emit laser light, a housing, a crystalline microresonator disposed within the housing, and a photonic integrated circuit disposed within the housing, the photonic integrated circuit including an optical waveguide network and configured to generate a clock signal based on the laser light. The RF oscillator system may further include at least one photonic wirebond configured to couple the laser light between the optical waveguide network and the crystalline microresonator via evanescent coupling; laser control circuitry disposed within the housing and configured to lock a frequency of the laser light to a resonance of the microresonator to generate the clock signal; and a direct digital synthesizer disposed within the housing and configured to produce a tunable oscillator signal based on the clock signal.

### STATEMENT OF GOVERNMENT INTEREST

This invention was made with United States Government assistance under Grant No. HR001122C0039 awarded by the Defense Advanced Research Projects Agency. The United States Government has certain rights in this invention.

### FIELD OF DISCLOSURE

The present disclosure relates to laser systems and, more particularly, to a compact packaged laser-driven RF oscillator.

### BACKGROUND

Electronic oscillators are used in a wide variety of applications. For example, radio frequency (RF) oscillators can generate periodic clock signals that can be used in digital electronics. RF oscillators can also be used to produce RF carrier frequencies used in radar systems or RF communication systems, for example. While some oscillator systems can produce stable, low-noise, RF signals, these systems can be large and may involve complex arrangements that can be sensitive to vibration or changes in temperature. In addition, such systems may offer limited frequency tuning and/or have high power consumption. While some more compact oscillator systems can provide greater frequency tuning and/or lower cost, they may not achieve the same phase noise performance as larger, more complex and/or power-hungry systems. Accordingly, non-trivial issues remain with respect to providing high performance, compact RF oscillators.

### SUMMARY

Aspects and examples provide compact, packaged photonic oscillator devices that exhibit low phase noise and broad frequency tunability.

According to one example, an RF oscillator system comprises a laser source configured to emit laser light, a housing, a crystalline microresonator disposed within the housing, and a photonic integrated circuit disposed within the housing, the photonic integrated circuit including an optical waveguide network and configured to generate a clock signal based on the laser light. The RF oscillator system further comprises a photonic wirebond configured to couple the laser light between the optical waveguide network and the crystalline microresonator via evanescent coupling, laser control circuitry disposed within the housing and configured to lock a frequency of the laser light to a resonance of the microresonator to generate the clock signal, and a direct digital synthesizer disposed within the housing and configured to produce a tunable oscillator signal based on the clock signal.

According to another example, an RF oscillator system comprises a housing, and a photonic subsystem disposed within the housing, the photonic subsystem include a laser diode, a crystalline microresonator, and photonic circuitry configured to produce a clock signal based on light emitted by the laser diode. The RF oscillator system further comprises laser control circuitry disposed within the housing, the laser control circuitry includes a Pound-Drever-Hall control loop configured to lock a frequency of the light emitted by the laser diode to a quiet point of the microresonator, and a direct digital synthesizer disposed within the housing and configured to produce an oscillator output signal based on the clock signal, a frequency of the oscillator output signal being tunable over an output frequency range.

According to another example an RF oscillator system comprises a housing, a laser diode disposed within the housing and configured to emit laser light, a photonic integrated circuit (PIC) disposed within the housing, the PIC including an optical waveguide network and configured to generate a clock signal based on the laser light, a crystalline microresonator disposed within the housing, a photonic wirebond configured to couple the laser light between the optical waveguide network and the crystalline microresonator via evanescent coupling, laser control circuitry disposed within the housing and configured to lock a frequency of the light emitted by the laser diode to a quiet point of the microresonator, and a direct digital synthesizer disposed within the housing and configured to produce a tunable oscillator output signal based on the clock signal.

Still other aspects and advantages of these examples are described in detail below. Examples disclosed herein may be combined with other examples in any manner consistent with at least one of the principles disclosed herein, and references to “an example,” “some examples,” “an alternate example,” “various examples,” “one example” or the like are not necessarily mutually exclusive and are intended to indicate that a particular feature, structure, or characteristic described may be included in at least one example. The appearances of such terms herein are not necessarily all referring to the same example.

### BRIEF DESCRIPTION OF THE DRAWINGS

In the figures:

FIG. 1 is a block diagram of an RF oscillator system according to an example;

FIG. 2 is a block diagram of the RF oscillator system of FIG. 1, according to an example;

FIG. 3A is a diagram illustrating a side view of a photonic wirebond providing a coupling mechanism between a photonic integrated circuit and a crystalline microresonator according to an example;

FIG. 3B is a diagram illustrating a plan (top) view of an example of the photonic wirebond, photonic integrated circuit, and crystalline microresonator of FIG. 3A;

FIG. 4A is a diagram of a loopback photonic wirebond according to an example;

FIG. 4B is a diagram showing a portion of the loopback photonic wirebond of FIG. 4A having an elliptical profile according to an example;

FIG. 5 is a block diagram of the RF oscillator system of FIG. 1, according to an example;

FIG. 6 is a block diagram of a tuning circuitry for a laser diode, according to an example;

FIG. 7 is a block diagram of a portion of the laser control circuitry for the RF oscillator system of FIG. 1, according to an example;

FIG. 8 is a graph illustrating a frequency relationship between a clock signal produced by the RF oscillator system of FIG. 1 and a resonance frequency of a microresonator included in the RF oscillator system of FIG. 1, according to an example;

FIG. 9A is a block diagram showing circuitry of a direct digital synthesizer that can be used in the RF oscillator system of FIG. 1, according to an example;

FIG. 9B is a block diagram showing aspects of the direct digital synthesizer of FIG. 9, according to an example;

FIG. 10 is a block diagram of a packaged RF oscillator system, according to an example;

FIG. 11A is a block diagram illustrating a top-down view of a packaged RF oscillator system, according to an example; and

FIG. 11B is a block diagram illustrating a side view of the packaged RF oscillator system of FIG. 11A, according to an example.

Although the following detailed description will proceed with reference being made to illustrative examples, many alternatives, modifications, and variations thereof will be apparent in light of this disclosure.

### DETAILED DESCRIPTION

A compact, packaged photonic oscillator with low phase noise is disclosed. The oscillator can be used, for example to generate a tunable radio frequency (RF) signal using fast frequency synthesis. According to certain examples, an RF oscillator uses a laser-driven microresonator to produce a high-frequency clock signal that is fed to a direct digital synthesizer (DDS) to produce a tunable RF output signal. Techniques are disclosed herein for coupling optical signals between a crystalline optical microresonator and signal carriers (e.g., optical waveguides) in a photonic integrated circuit (PIC). The techniques can be used, for instance, to allow for integration of the microresonator and the PIC into a package that is relatively compact and vibrationally robust. Furthermore, integrated control circuitry can be provided to stabilize, or lock, the frequency of the laser to a chosen narrow resonance, allowing for generation of a precise and stable clock signal. Using digital control and frequency tuning in combination with a high-Q microresonator (e.g., having a Q of approximately 10⁸ or higher), examples disclosed herein can provide an oscillator system having low phase noise, sub-nanosecond (ns) tuning agility, and fine frequency tuning over a broad output frequency range.

According to certain examples, an RF oscillator system includes a housing, a photonic integrated circuit disposed within the housing, and a crystalline microresonator disposed within the housing. The housing can be relatively compact, in some examples, having an internal volume of less than 10 cubic centimeters. The RF oscillator system may further include a laser source (e.g., a laser diode) configured to emit laser light. The laser source can be disposed within the housing or external to the housing and coupled to the photonic integrated circuit via a coupling mechanism, such as a fiber coupler, for example. The photonic integrated circuit includes an optical waveguide network and is configured to generate a clock signal based on the laser light. In some examples, the RF oscillator system includes a photonic wirebond configured to couple the laser light between the optical waveguide network and the crystalline microresonator via evanescent coupling. The RF oscillator system may further include laser control circuitry disposed within the housing and configured to lock a frequency of the laser light to a resonance of the microresonator to generate the clock signal, and a direct digital synthesizer disposed within the housing and configured to produce a tunable oscillator signal based on the clock signal.

Numerous configurations and applications will be apparent in light of this disclosure.

### General Overview

Numerous systems and applications involve the use of an electronic oscillator. For example, oscillators can be used to generate periodic clock signals used in digital electronics, or precise RF carrier frequencies used in radar or RF communication systems. While an ideal oscillator generates a perfect signal at a single frequency, in practice numerous impairments (such as environmental conditions that affect coupling and/or imperfections in in the electronic circuitry and/or components, for example), quantified as phase noise, limit the performance of RF systems. In some applications, large (e.g., rack-mounted), high-power oscillators are used to achieve very low phase noise. However, such devices are unsuitable for certain applications, such as in portable systems, for example, and may suffer from other drawbacks, such as limited frequency tunability and high cost.

Accordingly, examples disclosed herein provide an oscillator system that may deliver excellent phase noise performance (e.g., below 100 dBc/Hz) in a compact package (e.g., <10 cubic centimeters (ccm)). Examples use a photonic source with a high-Q optical microresonator to provide an accurate, fixed-frequency clock signal that drives an electronic direct digital synthesizer (DDS) to provide broad tunability (e.g., over a frequency range of 1-40 GHz). In some examples, an optical signal from a laser diode (or other laser source) is coupled to a crystalline optical microresonator using photonic wirebonding that avoids the need for active alignment to achieve reliable optical coupling. The microresonator can be integrated with other photonics components into a compact photonic integrated circuit (PIC). Furthermore, in some examples, laser/photonic control electronics are provided on a low-power, compact integrated circuit (IC) that can be co-located with the PIC. The PIC, the laser controller IC, and frequency tuning electronics (e.g., DDS and associated circuitry) can be combined into a compact, low-power package that is insensitive to vibration and thermal variations, while delivering ultra-low phase noise (e.g., <150 dBc/Hz), sub-nanosecond tuning agility, and <100 Hz fine frequency tuning steps across a wideband (e.g., 0-40 GHz) output range.

For example, according to certain examples, an RF oscillator system includes a laser source (e.g., a laser diode) that emits laser light, a housing, a photonic integrated circuit disposed within the housing, and a crystalline microresonator disposed within the housing. The photonic integrated circuit may include an optical waveguide network formed thereon or otherwise integrated with the photonic integrated circuit. The photonic integrated circuit is configured to generate a clock signal based on the laser light. The RF oscillator system may further include a photonic wirebond coupled to the optical waveguide network and configured to couple the laser light between the optical waveguide network and the crystalline microresonator via evanescent coupling. In some examples, the RF oscillator system further includes laser control circuitry disposed within the housing and configured to lock a carrier frequency of the laser light to a resonance of the microresonator to generate the clock signal, and a direct digital synthesizer disposed within the housing and configured to produce a tunable oscillator signal based on the clock signal. As previously discussed, existing oscillator systems can be large and may involve complex arrangements that can be sensitive to vibration and temperature changes. This large size prevents the deployment of the oscillator systems on platforms that are sensitive to size, weight, power, and cost (SWaP-C). For example, various United States Government agencies seek the deployment of electronic oscillators on unmanned air vehicles with limited payload space. As such, the housing according to certain examples disclosed herein can be relatively compact. For instance, in some cases, the housing is about 2 to 5 centimeters long, about 2 to 5 centimeters wide and about 0.5 to 1.5 centimeters tall. In some such cases, housing has an internal volume of less than about 50 cubic centimeters, less than 20 cubic centimeters, or less than 10 cubic centimeters. Other examples may have different dimensions.

These and other features of RF oscillators systems are described in more detail below.

### Example Device Architecture

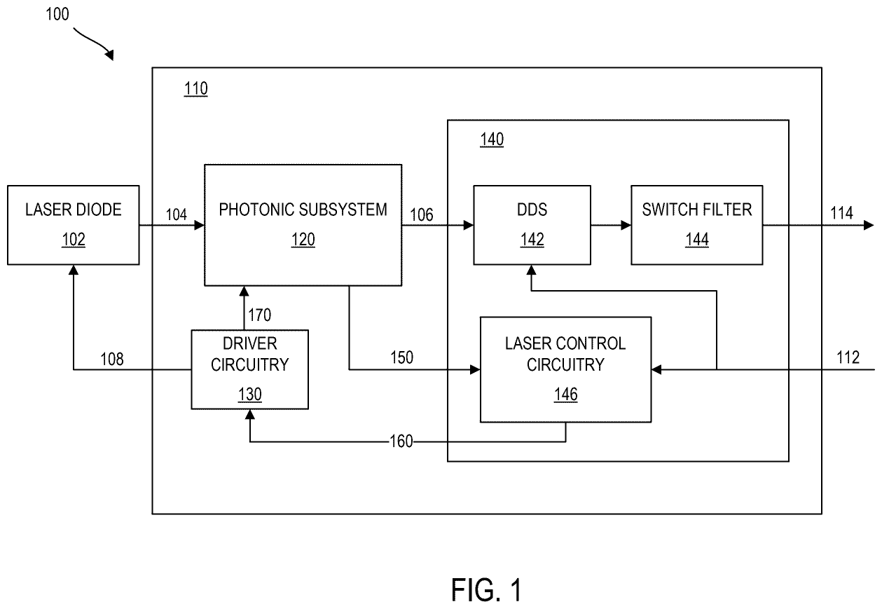

FIG. 1 is a block diagram of an RF oscillator system 100 according to an example. The RF oscillator system 100 includes a laser diode 102, a photonic subsystem 120, and driver circuitry 130. The RF oscillator system 100 further includes an electronics substrate 140 on which may be implemented a direct digital synthesizer (DDS) 142, a switch filter 144, and laser control circuitry 146. In some examples, the DDS 142 includes one or more integrated circuits (ICs) mounted on the electronics substrate 140. According to certain examples, the laser diode 102 is temperature stabilized and actively frequency stabilized to a high-Q microresonator (in the photonics subsystem 120) through the use of offset Pound Drever Hall (PDH) locking implemented by the laser control circuitry 146. In some examples, the laser control circuitry 146 includes a single integrated circuit (IC) mounted on the electronics substrate 140. As described in more detail below, certain circuitry having high current or power requirements, and/or high associated coupled transient noise (e.g., some or all of the driver circuitry 130) can be implemented separately from the laser control circuitry IC, while all control components can be integrated into a low power, compact IC. In examples, to achieve a compact, integrated solution, control functionality is implemented using digitally controlled servo loops for frequency stabilization and noise control, direct digital synthesis for modulation, and digital control of the laser bias current. The use of digital electronics, rather than analog systems, may provide higher accuracy control while consuming less power and producing less noise.

The photonic subsystem 120, the electronics substrate 140 (along with the DDS 142, the laser control circuitry 146, and the switch filter 144) may be part of a system package 110, which may include a housing and/or carrier substrate. For example, the system package 110 may include a housing in which the photonic subsystem 120 and the electronics substrate 140 are housed. In another example, the system package 110 includes a carrier substrate on which the photonic subsystem 120 and the electronics substrate 140 are mounted. In some examples, some or all of the driver circuitry 130 is included in the system package 110. In some example, at least some of the driver circuitry 130 is external to the system package 110 to allow scaling to meet different application specifications. In some examples, the laser diode 102 is part of the system package 110. For example, the laser diode 102 can be considered part of the photonic subsystem 120. In other examples, the laser diode 102 is external to the system package 110, as illustrated in FIG. 1, and laser light 104 from the laser diode 102 is coupled into the system package 110 using a fiber coupler, free space optics, or another coupling mechanism, as described further below.

According to certain examples, the laser diode 102 emits the laser light 104 that is directed to components of the photonic subsystem 120. Photonic circuitry in the photonic subsystem 120, including a microresonator as described further below, generates a fixed, high-speed/high-frequency clock signal 106 based on the laser light 104. In some examples, the DDS 142 receives the clock signal 106, along with a low-speed/low-frequency input signal 112, and (optionally together with the switch filter 144) produces an output signal 114 having a frequency that is tunable over a wide range. The input signal 112 may also be used by one or more elements of the laser control circuitry 136, as described further below. In some examples, the photonic subsystem 120 provides an approximately (e.g., ±10%) 50 Gigahertz (GHz) clock signal 106, the input signal 112 is a 100 MHz signal, and the DDS 142 and switch filter 144 provide a tunable output signal 114 having a frequency that is tunable over a range of 1-40 GHz.

In some examples, the laser control circuitry 146 receives one or more measurement signals 150 from the photonic subsystem 120 and produces one or more control signals 160 based on the measurement signals 150 and/or the input signal 112, as described further below. The driver circuitry 130 receives the control signals 160 from the laser control circuitry 146. Based on the control signals 160, the driver circuitry 130 may produce a laser bias current 108 that is used to drive the laser diode 102, as described further below. The driver circuitry may further produce, based on the control signals 160, one or more drive signals 170 that are used to drive, and/or adjust characteristics of, circuitry on the photonic subsystem 120, as also described further below.

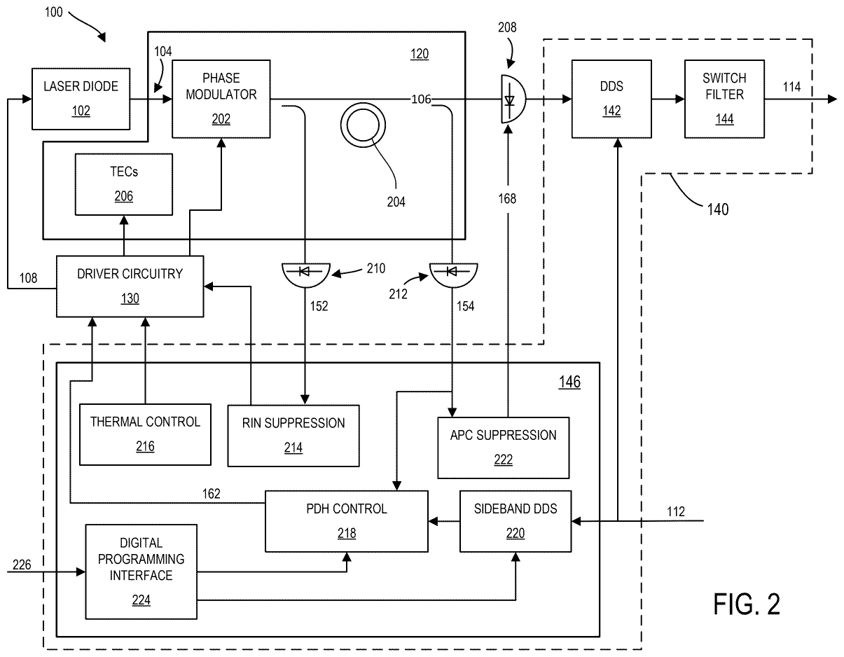

Turning now to FIG. 2, there is illustrated a block diagram of the RF oscillator system 100 of FIG. 1, according to certain examples. In this example, the photonic subsystem 120 includes a phase modulator 202, a microresonator 204, and one or more thermoelectric coolers 206 (referred to herein as the TECs 206). The TECs 206 provide thermal regulation for the photonic subsystem 120 and/or certain components thereof, as described further below. It will be appreciated that the TECs 206 may cool or heat, depending on the polarity of an applied drive current from the driver circuitry 130. In some examples, the phase modulator 202 is implemented as a Mach-Zender interferometer (MZI); however, in other examples, another type of phase modulator may be used. In some examples, at least some of the components of the photonic subsystem 120 (e.g., the phase modulator 202, optical waveguides, filters, and/or other circuitry) may be integrated into a photonic integrated circuit (PIC), which may be implemented on a silicon nitride substrate, for example.

According to certain examples, the laser diode 102 is a distributed feedback laser (DFB). The laser diode 102 emits the laser light 104 that is modulated by the phase modulator 202 and used to drive the microresonator 204 to produce the clock signal 106. As described further below, the clock frequency is determined by a spacing between comb teeth of a Kerr frequency comb that can be produced by the microresonator 204. In some examples, the clock signal 106 is a fixed 50 GHz clock signal (e.g., ±10%); however, in other examples, a different clock frequency can be selected. In some examples, the frequency of the clock signal 106 can be selected by selecting a particular size of the microresonator 204. A photodetector 208 may be used to couple the clock signal 106 to the DDS 142. The DDS 142 receives the clock signal 106 and the input signal 112 and provides tuning to control the frequency of the tunable output signal 114. The switch filter 144 may implement various filtering to condition the output signal 114 and switching to control the frequency of the output signal 114. Operation of the DDS 142 and switch filter 144 are described further below. The modulated laser light 104 may be sampled using a photodetector 210 and the clock signal 106 may also be sampled using a photodetector 212 to provide at least some of the measurement signals 150 (e.g., measurement signals 152 and 154 illustrated in FIG. 2) to various components of the laser control circuitry 146, as described further below.

The laser control circuitry 146 provides control functionality to control operating parameters of the laser diode 102, such as the output power level, and also provides temperature stabilization control for the laser diode 102. As described further below, in certain examples, the laser control circuitry 146 provides all control functions for the laser diode 102, including temperature control, noise suppression, bias control, and sideband tuning for the light 104 emitted from the laser diode 102. The laser control circuitry 146 may further provide active frequency stabilization for the laser diode 102. In particular, in certain examples, the output 104 from the laser diode 102 is frequency stabilized to the high-Q microresonator 204 through the use of offset Pound-Drever-Hall (PDH) locking. As shown in FIG. 2, in certain examples, the laser control circuitry 146 includes relative intensity noise (RIN) suppression circuitry 214, thermal control circuitry 216, a PDH control loop 218, a sideband direct digital synthesizer (DDS) 220, and amplitude to phase noise conversion (APC) suppression circuitry 222. Examples of these components and functionality are described further below.

Still referring to FIG. 2, in some examples, the laser control circuitry 146 is fully configurable and programmable via a digital programming interface 224. The digital programming interface 224 may allow for digital tuning and configuration of various components of the system, including the PDH control loop 218, the sideband DDS 220, and the thermal control circuitry 216. The digital programming interface may include an I2C or SPI serial interface, for example. The digital programming interface 224 receives control information, in the form of one or more digital configuration signals 226 from one or more external sources, and in turn provides control signals to the PDH control loop 218, the sideband DDS 220, and the thermal control circuitry 216 to control various parameters of each component. For example, for the sideband DDS 220, parameters such as the frequency (e.g., set by a DDS frequency control word) and modulation depth can be controlled/specified via the digital programming interface 224. For the PDH control loop 218, several parameters, such as the gain of various stages, sidetone phase shift, DC offset, etc., can be controlled/specified via the digital programming interface 224. Similarly, characteristics such as the gain and temperature settings of the thermal control circuitry 216 can be controlled/specified via the digital programming interface 224. These and other examples are described further below.

In some examples, to produce the tunable output signal 114 having a tuning frequency range of 1-40 GHz, the DDS 142 is supplied with the clock signal 106 from the photonic circuitry (e.g., the laser diode 102 and the photonic subsystem 120) that has a frequency above 40 GHz (e.g., approximately (e.g., ±10%) 50 GHz in some examples). The frequency of the clock signal 106 may be set by the free spectral range (FSR) of the microresonator 204. In one example, the micro-resonator 204 is a bulk crystalline microresonator, such as a magnesium fluoride (MgF₂) microresonator. Crystalline optical microresonators offer several advantages, such as compact size and the ability to be mass-manufactured from a variety of materials, including MgF₂. For example, for a MgF₂ microresonator, a 50 GHz FSR corresponds to a diameter size of approximately 1.7 millimeters (mm). In addition, MgF₂ optical microresonators can support ultra-high quality factors (e.g., Q≈1 billion) in the ultraviolet to mid-infrared wavelength range, with higher Q-factor corresponding to lower threshold power. Furthermore, MgF₂ optical microresonators have a relatively large effective mode area (volume) and therefore relatively lower thermorefractive noise (TRN), which can be a limiting factor in certain applications, including laser frequency stabilization.

Dissipative Kerr solitons form the basis of soliton microcombs, which are stable femtosecond-short light pulses circulating inside a microresonator. When pump light is coupled from the laser diode 102 into the microresonator 204, under certain resonance conditions, light builds up within the microresonator 204 and as the coupled optical power increases, non-linear effects can start to be observed. These non-linear effects can produce Kerr frequency combs. When the peak optical power circulating in the microresonator 204 crosses a certain threshold, soliton fission occurs and a soliton step is produced. Natural anomalous dispersion in MgF₂ in the GHz frequency range, in combination with low TRN, allow dissipative Kerr solitons to be generated at low power (e.g., in the milliwatt range) and with stable, high repetition rates, in a high-Q MgF₂ microresonator. These solitons can generate stable, low-noise microwave-frequency tones. With the frequency of the laser light 104 locked to the resonance of the microresonator 204 (e.g., using a PDH control loop 218 as described further below), the clock signal 106 can thus be generated at low power and having very low phase noise.

As noted above, crystalline optical microresonators (e.g., MgF₂ microresonators) can offer numerous benefits; however, achieving good, reliable optical coupling to crystalline microresonators can be challenging. To address this issue, certain examples employ techniques for providing a compact, manufacturable, and robust evanescent coupling solution. In particular, certain examples use a photonic wirebond evanescent coupler configured with a geometry that allows the photonic wirebond to couple light between circuitry or signal carriers (e.g., a waveguide) on a PIC and the microresonator 204. According to some such examples, the photonic wirebond is formed with a loop structure having a geometry (e.g., profile, length, loop dimensions) that is suitable for evanescent coupling with the crystalline microresonator. Evanescent coupling is a process by which electromagnetic waves are transmitted from one medium to another via the evanescent, exponentially decaying electromagnetic field. Coupling may be usually accomplished by placing two or more electromagnetic elements, such as optical waveguides, close together so that the evanescent field generated by one element does not decay much before it reaches the other element. For example, evanescent coupling can be achieved though Frustrated Total Internal Reflection (FTIR) in which an evanescent field very close to the surface of a dense medium at which a wave normally undergoes total internal reflection overlaps another dense medium that is close by. This overlap of the evanescent field disrupts the totality of the reflection, diverting some power into the second medium. Using a photonic wirebond as an evanescent coupler allows a high-Q crystalline microresonator to be packaged with a PIC and associated thermal regulation components and circuitry to produce a compact and vibrationally robust photonic subsystem 120.

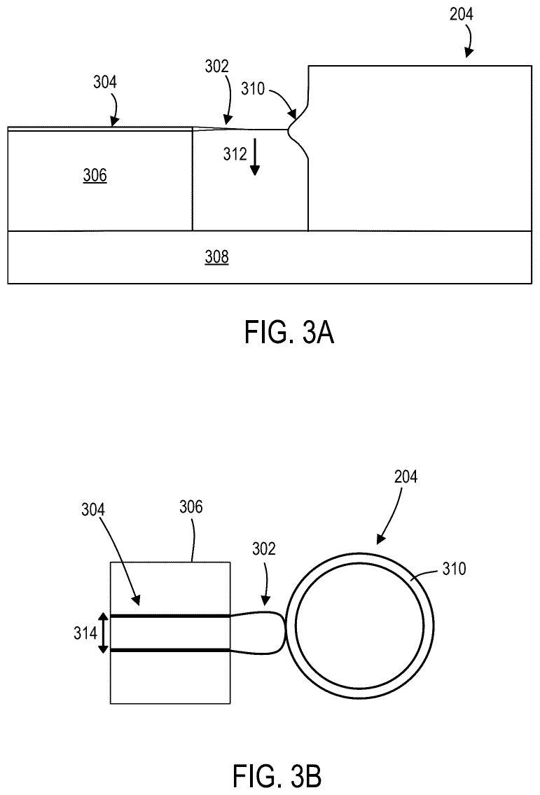

Referring to FIGS. 3A and 3B, there is illustrated an example of a portion of the photonic subsystem 120, including the microresonator 204 and a PIC 306. A photonic wirebond 302 is used to couple an optical waveguide 304 formed on the PIC 306 to the microresonator 204. In the example shown in FIG. 3A, the PIC 306 and the microresonator 204 are mounted on an integration substrate 308. In some instances, the combination of the PIC 306, microresonator 204, photonic wirebond 310, and the integration substrate 308 may also be considered a PIC. As described above, although not shown (for simplicity) in FIGS. 3A and 3B, the PIC 306 may include various circuitry and/or components of the photonic subsystem 120, such as the phase modulator 202, for example. Accordingly, the optical waveguide 304 may be used to transfer the light 104 from the laser diode 102, via the phase modulator 202, to the photonic wirebond 302 for coupling to the microresonator 204. Similarly, the optical waveguide 304 may be used to transfer the clock signal 106 from the microresonator 204 to the photodiode 208, for example. Although a single waveguide 304 and a single photonic wirebond 302 are illustrated in FIGS. 3A and 3B for simplicity and explanation, it will be appreciated that in some applications, multiple waveguides 304 and/or photonic wirebonds 302 may be used, depending on the nature and/or complexity of the circuitry of the PIC 306 (or photonic subsystem 120).

As shown in FIGS. 3A and 3B, in some examples, the microresonator 204 is formed with a protrusion 310 such that a diameter of the microresonator 204 in the region of the protrusion 310 is larger than a diameter of the remainder of the body of the microresonator 204. In some examples, the microresonator 204 is circular in cross-section (e.g., generally having a cylindrical shape), and the protrusion 310 is an annular protrusion that extends around a circumference of the microresonator 204, as shown in FIG. 3B. In some examples, the microresonator 204 is forming using a diamond-turning lathe to produce the desired geometry. After the diamond-turning step(s), the microresonator 204 may be polished with a series of diamond slurries to produce a smooth surface and high Q.

Crystalline MgF₂ microresonators are highly multimode, meaning that they can support multiple fundamental and higher-order transverse whispering gallery modes. In some examples, the microresonator 204 is formed with the protrusion 310 having a relatively large cross-section, such that the microresonator 204 can attain an ultrahigh Q-factor (e.g., >10⁹) for both the fundamental and higher-order mode families. Accordingly, multiple mode families may support soliton formation, significantly relaxing mode-matching conditions and facilitating coupling of the light 104 emitted from the laser diode 102 into the microresonator 204 for the soliton generation. In addition, the multimode structure may allow for the presence of avoided mode crossings (AMX), which originate from the interaction and hybridization of different mode families. Avoided mode crossings, in turn, may allow for the presence of “quiet points,” which are ranges of pump-resonator detuning where the soliton microcomb repetition rate noise is suppressed, allowing for the generation of exceptionally low-noise microwave tones.

Quiet points correspond to local maxima in the repetition rate of the soliton microcomb, and may be located via direct detection of the microcomb beat note. Quiet points can occur in detuning regions having a certain bandwidth (e.g., ˜100 kHz) around avoided mode crossings. Quiet point operation reduces the phase noise at certain frequency offsets (e.g., ˜10 kHz) from the central frequency of the RF carrier. According to certain examples, once a position of a quiet point is detected, the laser control circuitry 146 can lock the frequency of the light 104 emitted by the laser diode 102 (the pump) to the corresponding offset position via the PDH control loop 218. Thus, low-noise operation can be achieved and maintained.

Continuing with the example of FIGS. 3A and 3B, in certain examples, the optical waveguide 304 is configured as a high-aspect ratio, multi-mode, low-loss waveguide. As described above, in some examples, the PIC 306 includes a silicon nitride substrate on which the optical waveguide 304 may be formed. However, in other examples, other substrate materials can be used. In some examples, the photonic wirebond 302 is formed as a “loopback” structure extending between two conductive traces of the optical waveguide 304, as shown in FIG. 3B, for example. In some examples, the PIC 306 and the microresonator 204 are positioned on the integration substrate 308 spaced apart from one another. Accordingly, the photonic wirebond 302 may extend from the PIC 306 across a gap towards, and optionally to contact, the protrusion 310 on the microresonator 204, as shown in FIGS. 3A and 3B. In some examples and orientations of the RF oscillator system 100, the downward force of gravity on the photonic wirebond 302 as it extends across the gap (indicated by arrow 312) can cause the photonic wirebond 302 to droop downwards, rather than remain in a perfectly level plane. Accordingly, the alignment of the photonic wirebond 302 with the microresonator 204 and/or an extension length of the photonic wirebond 302 (e.g., a length/distance measured from ends of the photonic wirebond 302 attached to the optical waveguide 304 and a tip region, or furthest extension of the loop away from the ends of the photonic wirebond 302) may be tailored to account for some droop. For example, the photonic wirebond 302 can be initially aligned slightly above the midpoint (or “equator”) of the protrusion 310 of the microresonator 204, such that as gravity-induced droop causes the at least the end of the photonic wirebond 302 to bend downwards, the tip region of the loop contacts and rests against the protrusion 310. This configuration may naturally and advantageously provide some resilience or robustness of the coupling to vibration or other mechanical perturbances.

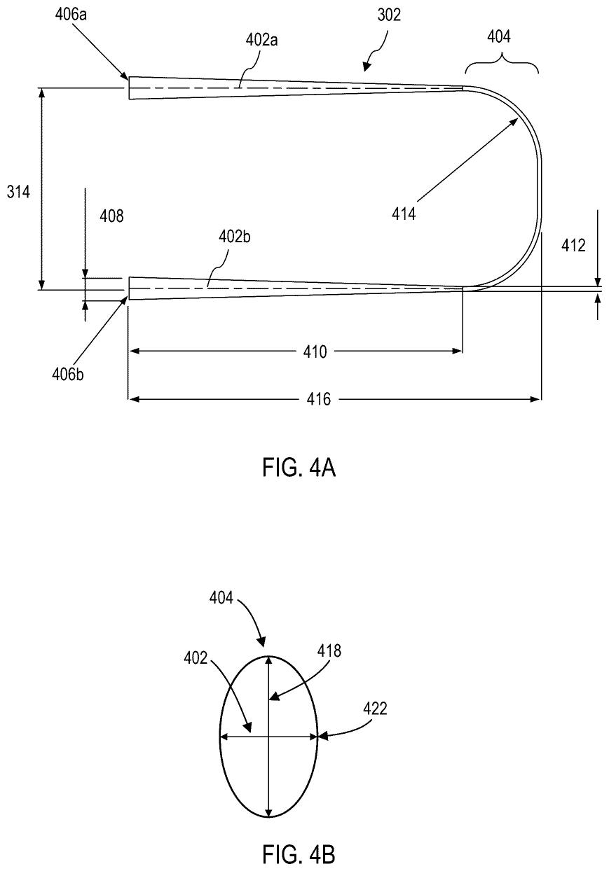

Referring now to FIG. 4A, there is illustrated a diagram showing a structure of the loopback photonic wirebond 302 according to some examples. In this example, the photonic wirebond 302 includes two end regions 402a, 402b, and a U-shaped loopback portion 404 extending between the two end regions 402a, 402b. The end regions 402a, 402b have fixed face anchor points 406a, 406b, respectively, that provide a waveguide interface and can be used to anchor the photonic wirebond 302 to the optical waveguide 304. The anchor points 406a, 406b can be written onto coupling facets of the optical waveguide 304 using a two-photon polymerization process, for example.

In some examples, the end regions 402a, 402b include tapered portions. The tapered portions may have a circular profile (or cross-section). In one example, a first diameter 408 of the tapered portions at the fixed face anchor points 406a, 406b, may be approximately 15 μm (e.g., 15 μm±<10%). The end regions 402a, 402b, may taper in diameter over the length 410 of the individual end regions to a second diameter 412 at a junction with the loopback portion 404. In one example, the second diameter 412 may be approximately 2 μm (e.g., 2 μm±<10%). According to certain examples in which microresonator 204 is made of MgF₂, these particular values for the diameters 408, 412 are selected because the effective index (neff) for the fundamental TE mode can be engineered through the photonic wirebond geometry to match that of MgF₂. In other examples or for other applications, different diameter values may be selected. In some examples, the length 410 of the end regions 402a, 402b may be at least 40 μm to ensure efficient coupling. For example, the length 410 of the end regions 402a, 402b may be in a range of about 40 μm to 250 μm, or 100 μm to 250 μm, or in some examples, approximately 210 μm (e.g., 210 μm±<10%). In some examples, the photonic wirebond 302 is unclad (e.g., “air clad” where air acts as the cladding material) to preserve microresonator coupling performance.

In some examples, at least a portion of the loopback portion 404 has an elliptical profile or cross-section, as shown in FIG. 4B, for example. In some examples, the major diameter 418 of the elliptical portion is approximately double the dimension of the minor diameter 420. In some examples, the minor diameter 420 is selected to substantially match the second diameter 412 (e.g., to be the same as the second diameter within a small or otherwise acceptable margin of error, such as <1%, for example). In one example, the minor diameter 420 is approximately 2 μm (e.g., 2 μm±<10%) and the major diameter 418 is approximately 4 μm (e.g., 4 μm±<10%). The loopback portion 404 may be oriented such that the major diameter 402 is substantially parallel to the surface of the microresonator 204, such that the loopback portion 304 has a contact region 422 that contacts the protrusion 310 of the microresonator 204, as shown in FIG. 3B, for example. The use of an elliptical coupler may be advantageous in that it allows for tuning in two dimensions which may allow individual tuning of different characteristics or parameters of the coupler. For example, the coupling efficiency can be tuned by tuning the minor diameter 420 to keep the loopback portion 404 relatively narrow in one dimension, which allows more light to be coupled into the microresonator 204 via a greater extent of the evanescent field (higher coupling efficiency). Elongating the major diameter 418 increases the surface area of the coupling region of the photonic wirebond 302, which allows the photonic wirebond 302 to support higher optical power.

Referring again to FIG. 4A, the end regions 402a, 402b and the loopback portion 404 may be regions of a single optical waveguide (such as an optical fiber or other optical waveguide structure/material) that is constructed with different geometric properties (e.g., diameter, taper, profile,) in the different regions. The loopback portion 404 has a radius of curvature 414. In some examples, the radius of curvature 414 is in a range of about 40 μm to 55 μm, or 45 μm to 50 μm, or in some examples, approximately 48.5 μm (e.g., 48.5 μm±<10%). The pitch 314 is the center-to-center spacing between conductors of the optical waveguide 304 to which the photonic wirebond 302 is to be coupled, and therefore corresponds to the center-to-center spacing between the end regions 402a, 402b. In some examples, the pitch 314 is in a range of about 100 μm to 250 μm, or in some examples, approximately 127 μm (e.g., 127 μm±<10%). In some examples, the extension length 416 of the photonic wirebond 302 is in a range of about 100 μm to 300 μm. Thus, the various aspects of the geometry of the loopback photonic wirebond 302 may be selected and tuned so as to provide a coupling mechanism that is capable of handling high optical power, while also being robust and repeatably manufacturable with good reliability. It will be appreciated, however, that photonic wirebonds as described herein may have different dimensions depending on a variety of factors, including the configuration of various components of the RF oscillator 100 in which the photonic wirebond 302 is used, and the dimensions provided herein are illustrative examples only and not intended to be limiting.

According to certain examples, the photonic wirebond 302 can be manufactured using additive three-dimensional (3D) printing techniques. The use of 3D printing allows the photonic wirebond 302 to be manufactured with precisely controllable, yet widely variable, dimensions and geometry that can be tailored to specific applications. In other examples, the photonic wirebond 302 can be formed using laser-based etching techniques. Other manufacturing techniques may also be used. In some examples, the photonic wirebond 302 can be made of a photoresist material, such as SU-8 (a negative-tone photoresist material), for example. The selection of SU-8 may be advantageous in some applications because its refractive index is a good match to the refractive index of MgF₂, which may be used for the microresonator 204, as described above.

As described above, the photonic wirebond 302 operates to couple light from the optical waveguide 304 into the microresonator 204, and from the microresonator 204 back into the optical waveguide 304, via evanescent coupling. Coupling to the microresonator 204 involves refractive index matching between the injected and circulating modes (k-vector matching), and benefits from a large evanescent field extent so as to facilitate light-material interaction. Both of these properties exhibit sensitivity to the geometry of the photonic wirebond 302. Accordingly, the photonic wirebond can be constructed according to examples described with reference to FIGS. 4A and 4B to achieve reliable evanescent coupling with the microresonator 204. Furthermore, in examples, the structure of the photonic wirebond 302 supports input/output ports written to coupling facets of the optical waveguide 304 with relatively low loss and high optical power. In some examples, the total losses from photonic wirebond to optical fiber facet junctions do not exceed 0.85 dB/facet (at a light wavelength of 1550 nm) and support power handling of more than 400 mW.

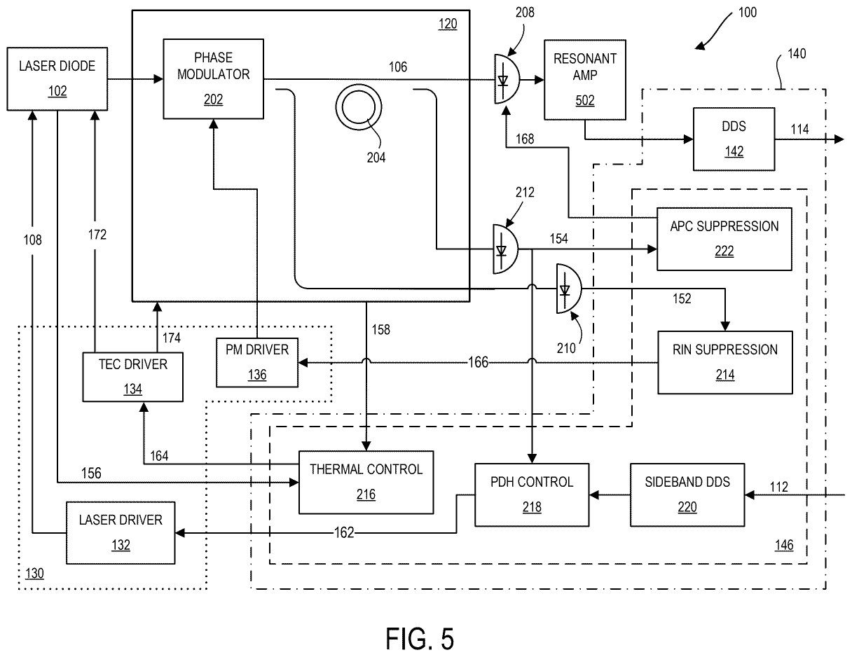

Turning now to FIG. 5, aspects of the laser control circuitry 146 and the driver circuitry 130 are described. According to certain examples, the driver circuitry 130 includes a laser driver 132, a TEC driver 134, and a phase modulator (PM) driver 136. The laser driver 132 produces the laser drive current 108. In some examples, the laser driver 132 feeds back on the laser driver current 108 based on the PDH control loop 218, as described below. Accordingly, the laser driver 132 may further modulate the laser diode 102 to generate an error signal for the PDH control loop 218, as described further below. The TEC driver 134 may receive control signals from the thermal control circuitry 216 and control the TECs 206 to stabilize the temperature of the photonic subsystem 120, the microresonator 204, and/or the laser diode 102. Examples of thermal control techniques are described further below. The PM driver 136 receives control signals from the RIN suppression circuitry 214 and drives the phase modulator 202, as also described further below.

As described above, the laser control circuitry 146 may be implemented in a single IC. In the example of FIG. 5, the laser driver 132 and the PM driver 136 are implemented external to the laser control circuitry IC. In addition, thermal management for the RF oscillator system 100 is partitioned into the on-chip thermal circuitry 216 and the external TEC driver 134. This partitioning allows “front-end” control for thermal stabilization of the laser diode 102 and the photonic subsystem 120 to be integrated into the IC of the laser control circuitry 146, while higher power components are implemented off-chip.

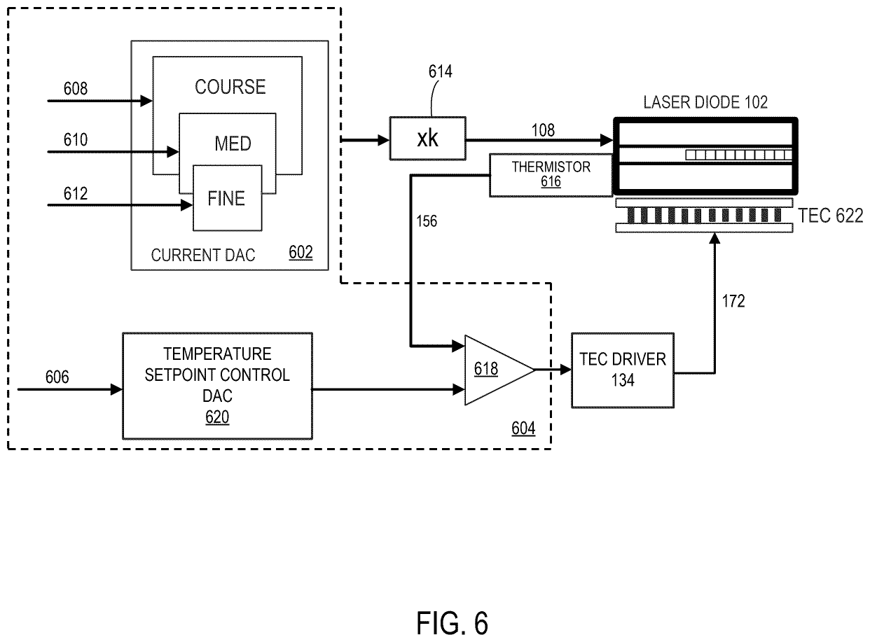

According to certain examples, a significant factor impacting the noise performance of the RF oscillator system 100 is the relative intensity noise (RIN) of the laser diode 102, which translates to microwave phase noise. As described above, in certain examples, the frequency of the output light beam 104 from the laser diode 102 is locked to a quiet point of the microresonator 204 to minimize phase noise. This frequency stabilization can be achieved using the PDH control loop 218. In some examples, a frequency scan can be performed to identify one or more quiet point resonances of the microresonator 204 for locking the laser diode 102 to stabilize the frequency of the clock signal 106. Traditionally, an analog ramp of the laser DC bias current can be used to perform this frequency scan. In contrast, according to certain examples, the frequency scan is performed digitally using a current digital-to-analog converter (DAC) 602, illustrated in FIG. 6. As described above, the use of digital electronics for various control features allows the laser control circuitry 146 to be implemented in a low voltage, small form-factor integrated package.

Referring to FIG. 6, there is illustrated a portion of the laser control circuitry 146, which may be implemented in a laser controller IC 604. According to certain examples, the current DAC 602 operates as a bias current controller that can be configured to provide coarse, medium (med), and fine tuning of the bias current 108 for the laser diode 102. Accordingly, the current DAC 602 may receive three control inputs 608, 610, 612, as shown in FIG. 6. In one example, each of the three control inputs is an 8-bit signal; however, in other examples, the control inputs may comprise another number of bits and the three inputs need not have the same number of bits. Each of the control inputs may be provided via the digital programming interface 224. Based on the control input 608, the current DAC 602 may set a coarse DC bias current 108 for the laser diode 102. In one example, this DC bias current 108 may be in a range of 0.6 A to 1.2 A. In some examples, to achieve this relatively high current level, the output from the current DAC 602 may be level shifted by a current multiplier 614. For example, the current multiplier 614 may multiply the amplitude of the current by a factor of k. In one example, k=100; however, other multiplication factors may be used. In some examples, the current multiplier 614 is part of the laser driver 132.

After the coarse DC bias current range has been set, the current DAC 602 can be controlled, via the control inputs 610 and 612, to sweep the DC bias current 108 over a set range so as to scan the laser frequency over a certain range to find resonances of interest, as described above. The current DAC 602 may be scanned over a programmable range and at a programmable scan rate. For example, to perform a frequency scan over a range of 30-300 MHz may correspond to tuning the DC bias current over a range of about 0.2-2 mA. Precise and programmable digital control allows the frequency scan to be performed with very fine precision over a desired scan range and without the need for conventional analog control. For example, the current DAC 602 can be configured to provide fine current resolution (e.g., in a range of approximately 0.5-1 μA based on the control input 612) equivalent to a frequency step of less than 100 kHz. In certain examples, the current DAC 602 can be programmed for a particular scan range and/or step frequency via the digital programming interface 224.

According to certain examples, temperature control can be used to sweep the laser frequency over twice the free spectral range to within a specified margin of an identified resonance frequency. Still referring to FIG. 6, in some examples, a thermistor 616 is coupled to the laser diode 102 and to a comparator 618 on the laser controller IC 604. The thermistor 616 may be used for temperature sensing, as described further below. A desired temperature, selected to tune the laser diode frequency to a particular frequency within the scan/sweep range, for example, may be set using a temperature setpoint control DAC 620. The temperature setpoint control DAC 620 provides a temperature setpoint signal, expressed as a DC current value, to one input of the comparator 618. The other input of the comparator 618 receives a thermistor sensing signal 156 (e.g., one of the measurement signals 150). The comparator 618 compares the signals received at its two inputs and provides an output signal to the TEC driver 134. The TEC driver 134 supplies a drive signal 172 (e.g., one of the drive signals 170) to a TEC 622 that is coupled to the laser diode 102 to adjust a temperature of the laser diode 102. Thus, the frequency of the laser diode 102 can be tuned by driving the TEC 622, via the TEC driver 134, to adjust the temperature of the laser diode 102. The comparator 618 and the temperature setpoint control DAC 620 may be part of the thermal control circuitry 216 (see FIGS. 2 and 5). The temperature setpoint may be specified by a temperature control signal 606 that may be input to the temperature setpoint control DAC 620 via the digital programming interface 224, for example. It will be appreciated that the laser driver 132 is not fully illustrated in FIG. 6. The circuitry of FIG. 6 is intended to conceptually illustrate tuning of the laser bias current 108 to select a particular resonance, rather than a complete implementation of the circuitry involved in driving the laser diode 102.

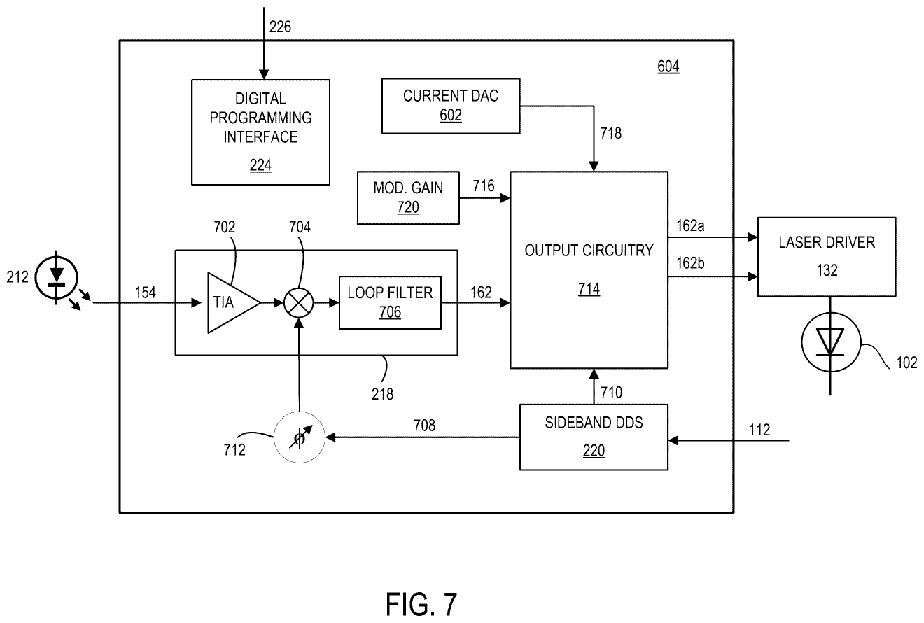

As described above, once a resonance frequency of the micro-resonator 204 has been selected, the PDH control loop 218 may be used to stabilize the frequency of the laser diode 102. Referring to FIG. 7, there is illustrated a portion of the laser control circuitry 146 including one example of components of the PDH control loop 218 according to certain aspects. The PDH technique allows for stabilizing the frequency of light emitted by the laser diode 102 by locking on to a stable cavity, such as the micro-resonator 204. Frequency stabilization may be needed for high precision laser applications because all lasers demonstrate frequency wander at some level. This instability may be due to temperature variations, mechanical imperfections, and laser gain dynamics (which change laser cavity lengths), laser driver current and voltage fluctuations, atomic transition widths, and many other factors. PDH locking addresses the problem of frequency wander by actively tuning the laser diode 102 to match the resonance condition of a stable reference cavity, in this case, the micro-resonator 204. In addition, by locking the frequency of the laser diode 102 to achieve operation at a quiet point of the microresonator 204, the phase noise in the clock signal 106 can be reduced.

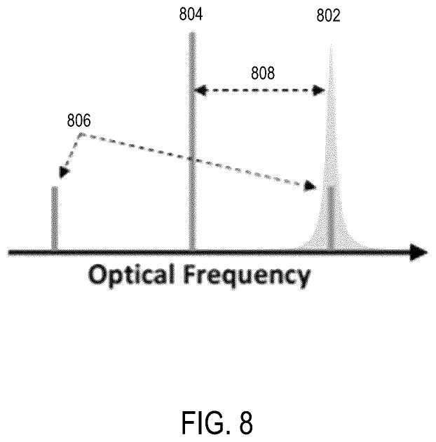

FIG. 8 is a graph showing an example of PDH frequency locking. The microresonator 204 produces a resonance peak 802. The laser light 104 is modulated for PDH locking, which causes the laser light 104 to include a carrier frequency 804 and two sidebands 806. The PDH control loop 218 can be configured to control the sidebands 806 and to lock the carrier frequency 804 to a specified offset distance 808 from the resonant peak 802 of the microresonator 204 to achieve quiet point operation.

Referring again to FIG. 7, the PDH control loop 218 may include a transimpedance amplifier (TIA) 702, a down-conversion mixer 702, and a loop filter 706. In some examples, the phase-modulated laser light 104 (which includes the carrier frequency 804 and the two sidebands 806) is sampled using a high speed photodetector 212, as illustrated in FIGS. 2 and 5, for example. The measurement signal 154 from the photodetector 212 is provided to the TIA 702. In some examples, the measurement signal 154 from the photodetector 212 is a current signal that corresponds to a 10-100 MHz sideband signal from the micro-resonator 204. Accordingly, the TIA 702 acts as an interface with the photodetector 212 and produces a voltage output to drive the down-conversion mixer 704.

Based on the low-frequency input signal 112 and digital control signals received via the digital programming interface 224, the sideband DDS 220 produces a reference signal 708 and a sideband modulation signal 710. Both signals 708, 710 have the same frequency that is set by a DDS frequency control word received via the digital programming interface 224. The sideband modulation signal 710 is used to provide tunable sideband modulation of the laser diode 102 over a specified frequency range. The reference signal 708 is provided to the mixer 704 in the PDH control loop 218. In some examples, the reference signal 708 is passed via a phase shifter 712 to tune the phase of the reference signal 708. In some examples, the resolution of the phase shifter 712, and the phase shift value, can be set by control signals received via the digital programming interface 224. The reference signal 708 is mixed with the output from the TIA 702 in the mixer 704. Because sideband DDS 220 produces both the reference signal 708 and the sideband modulation signal 710 that is used to control sideband modulation of the laser diode 102, the reference signal 708 is in phase with the original sideband modulation of the light 104 emitted from the laser diode 102. The output from the mixer 704 is provided to the loop filter 706. The resulting electronic control signal 162 output from the loop filter 706 gives a measure of how far the laser carrier is off resonance with the micro-resonator 204 and may be used as feedback for active frequency stabilization of the laser diode 102.

According to certain examples, the laser control circuitry 146 includes output circuitry 714. The control signal 162 from the PDH control loop 218 may be fed to the output circuitry 714, along with the sideband modulation signal 710, a modulation gain signal 716, and an output signal 718 from the current DAC 602. In some examples, the signals 162, 710, 716, and 718 are current signals, and therefore, the output circuitry 714 may include a current sum circuit. In some examples, the output signal 718 from the current DAC 602 is a current signal representative of the laser diode bias current 108 to be produced by the laser driver 132. As described above, the sideband modulation signal 710 from the sideband DDS 220 is used to tune sideband modulation of the laser diode 102. In some examples, sideband modulation signal 710 is sent to the laser diode 102, via the laser driver 132, as a current modulation that is superimposed on the DC bias current 108. Accordingly, the sideband modulation signal 710 can be added to the output signal 718 from the current DAC 602 by the output circuitry 714. The modulation depth may be set through a control signal received by the sideband DDS 220 via the digital programming interface 224 (e.g., as illustrated in FIG. 2). In some examples, a modulation gain DAC 720 provides digital control of a gain of the sideband tones via the modulation gain signal 716. The gain may be set via the digital programming interface 224. The control signal 162 from the PDH loop 218 is also added to the output signal 718 from the current DAC 602 by the output circuitry 714. The control signal 162 from the PDH control loop 218 “corrects” the DC bias current signal 108 provided to the laser diode 202 to stabilize the frequency of the laser light 104 to the microresonator quiet point that produces the clock signal 106, as described above. Thus, the output circuitry 714 provides a control signal to drive the laser driver 132 to produce a stable, low-noise, modulated bias current for the laser diode 102, the control signal including a DC portion 162a (e.g., representing the DC bias current) and a superimposed modulation portion 162b representing the sideband modulation.

As described above, locking the laser diode to a quiet point of the microresonator 204 using the PDH control loop 218 may reduce RIN associated with the laser diode 102. In addition, the phase modulator 204 may be configured to stabilize the laser intensity to further reduce/suppress RIN, and in turn, reduce phase noise in the clock signal 106. Accordingly, referring again to FIGS. 2 and 5, in some examples, the laser control circuitry 146 includes the RIN suppression circuitry 214. The RIN suppression circuitry 214 may receive samples of the amplitude of the laser light 104 emitted by the laser diode 102 via the photodiode 210 (measurement signal 152), as shown in FIGS. 2 and 5. In some examples, the RIN suppression circuitry 214 implements an intensity modulator in a closed loop servo system based on the samples from the photodiode 210 to generate a control signal 166 that is fed to the PM driver 136. RIN suppression may advantageously reduce short-term noise in the laser light 104 and improve performance of the RF oscillator system 100.

As described above, the photodiode 208 can be used to couple the clock signal 106 to the DDS 142. When illuminating the photodiode 208 with modulated laser light, optical intensity fluctuations of the incident beam are converted into phase fluctuations of the output electrical signal. This amplitude to phase noise conversion (APC) thus imposes a further constraint on the phase noise of the clock signal 106 when attempting to produce an ultra-low phase noise oscillator output signal 114. In some examples, the phase noise of the RF oscillator system 100 is dominated by APC at offset frequencies about ˜100 kHz. Accordingly, in some examples, the laser control circuitry 146 includes the APC suppression circuitry 222 configured to reduce phase noise caused by APC at the photodiode 208. In the illustrated example, the APC suppression circuitry 222 receives a sample of the clock signal 106 via the photodiode 212 (measurement signal 154) and produces a feedback control signal 168 to control one or more characteristics of the photodiode 208 to suppress APC. For example, the APC suppression circuitry 222 can be configured to adjust the optical input power, bias voltage, and/or matching circuit parameters of the photodiode 208 to minimize APC and achieve additional improvements in RIN. In one example, the APC suppression circuitry 222 is configured to adjust, based on the control signal 168, the bias voltage of the photodiode 208 to operate at an APC null of the photodiode 208.

As described above, temperature can affect the operating parameters and performance of the laser diode 102 and/or photonic circuitry in the photonics subsystem 120, and therefore, the RF oscillator system 100 includes circuitry to provide temperature stabilization and tuning. For example, temperature control of the PIC 306 and the microresonator 204 may be used to further achieve frequency stability in the clock signal 106. Temperature adjustment of the microresonator 204 can also be used as part of the laser frequency tuning process discussed above. In some examples, the thermal control circuitry 216 provides control signal(s) 164 to the TEC driver 134 to drive the TECs 206 to control the temperature of the laser diode 102, the microresonator 204, and/or the PIC 306 (or any of its components). In some examples, one or more TECs can be coupled to the photonic substrate (e.g., the integration substrate 308) on which components of the photonics subsystem 120 are mounted to provide package-level thermal stability. According to certain examples, the thermal control circuitry 216 implements a proportional-integral-derivative (PID) controller for each of the TECs 206. Accordingly, the thermal control circuitry 216 may receive temperature measurement signals 156 from the laser diode 102 (as described above) and temperature signals 158 from thermal sensors (e.g., thermistors) associated with the components of the photonics subsystem 120, including the microresonator 204, for example. The measurements can used, in combination with temperature setpoint information received via the digital programming interface 224, to produce the control signals 164 for the TEC driver 134. Based on the control signals 164, the TEC driver supplies drive signals to adjust heating or cooling effected by the TECs 206. As described above, the TEC driver 134 supplies the drive signal 172 to control the TEC 622 associated with the laser diode 102. The TEC driver 134 may also supply one or more driver signals 174 to drive the TECs associated with components of the photonics subsystem 120. For example, a TEC coupled to the microresonator 204 can be driven by the TEC driver 134 to reduce thermal drift in the microresonator 204. In some examples, the TEC driver 134 can be implemented using one or more H-bridge controllers.

Still referring to FIGS. 2 and 5, in some examples, the output power of the photodiode 208 used to couple the clock signal 106 to the DDS 142 is relatively low. Accordingly, the RF oscillator 100 may include a resonator amplifier 502 to increase the power of the signal input to the DDS 142. In some examples, the resonator amplifier 502 includes a resonator transimpedance amplifier (TIA) that converts the output current from the photodiode 208 to a voltage signal that drives the DDS 142. In one example, a resonator TIA implemented using compact microstrip high-Q resonance is capable of providing over 20 dBm output power above 20 GHz, which is more than sufficient to drive the DDS 142 for many applications. Accordingly, in some examples, the resonant amplifier 502 can be configured to provide lower than maximum gain to extend the operating frequency range while still maintaining low noise operation.

As described above, the DDS 142 can be used to produce the tunable output signal 114 based on the clock signal 106. In some examples, the DDS 142 translates the fixed 50 GHz clock signal output from the photonics subsystem 120 into the variable output signal 114 having a frequency that is tunable over a range of DC to 40 GHz. According to certain examples, the DDS 142 achieves the full range of output frequencies as a first Nyquist output (e.g., DC-25 GHz) and a second Nyquist output (e.g., (e.g., 25 GH-50 GHz). However, as both the first and second Nyquist outputs may appear simultaneously, the switch filter 144 may be used to isolate a desired output frequency for the tunable output signal 114. In some examples, tunable filtering implemented using the switch filter 144 allows selection of filters that reduce spurs for improved phase noise. For example, three prominent spurs that can occur above 1 MHz include the soliton S-resonance (a first spur), the combined soliton C-resonance and PDH modulation spur (a second spur), and APC noise caused by a RIN peak of the laser diode 102 (a third spur). Of these three, the C-resonance/PDH modulation spur (the second spur) may have the highest amplitude and therefore additional cancellation beyond the APC mitigation described above may be beneficial. This second spur occurs at the PDH offset frequency. As described above, the PDH offset frequency is generated in the laser control circuitry 146, and therefore, the offset frequency setpoint can be used to cancel the second spur in the DDS 142 and/or switch filter 144. The location of the S-resonance (first spur) varies with the optical power of the laser diode 102, and can be canceled after initial calibration of the RF oscillator 100 in which the output power of the photodetector 208 is mapped to the S-resonance frequency. Similarly, residual high-frequency RIN spurs can be mapped out during calibration of the RF oscillator system 100 and canceled in the DDS 142 and/or switch filter 144.

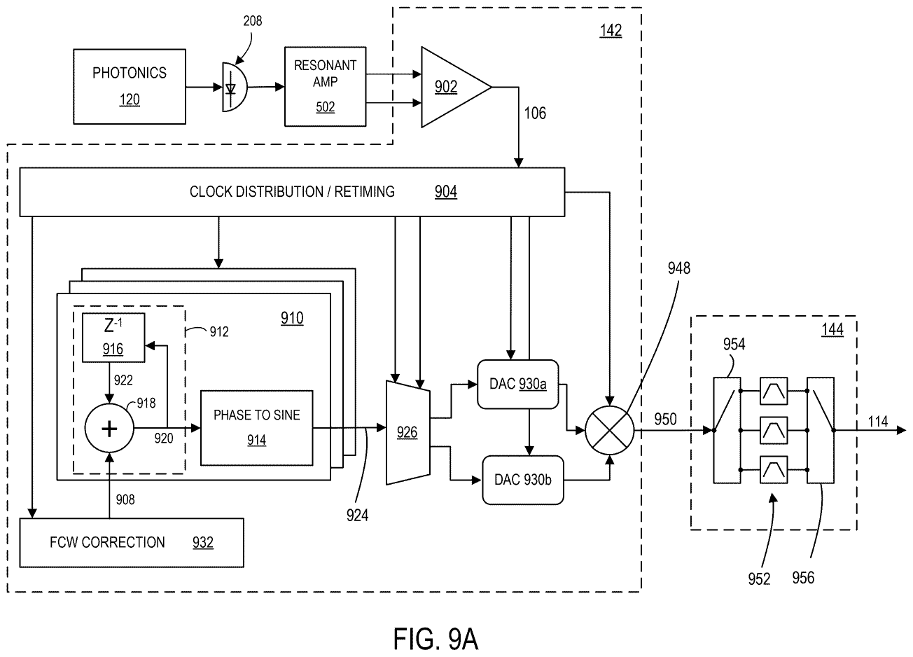

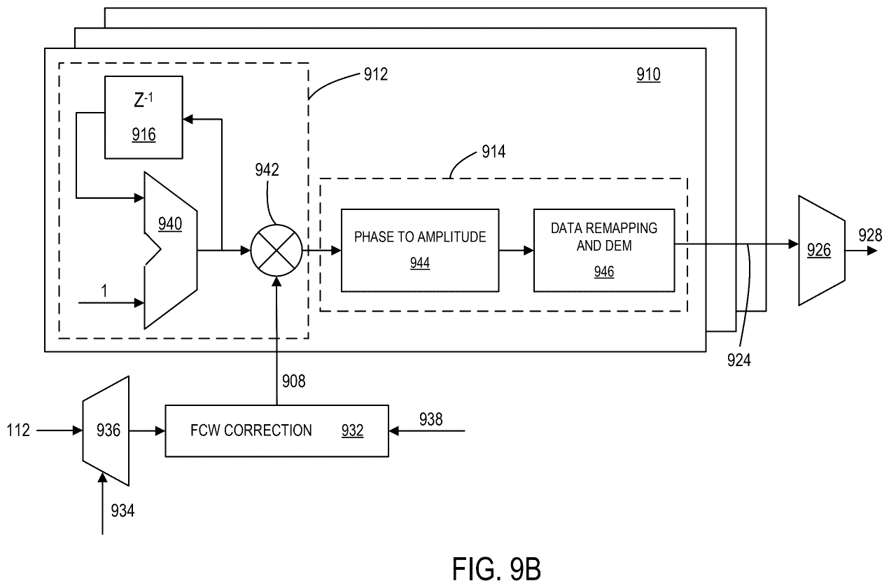

Referring to FIG. 9A, there is illustrated a block diagram of a portion of the RF oscillator system 100 showing an example of the DDS 142 and the switch filter 144. In this example, the DDS 142 includes a buffer 902 that receives the clock signal 106 from the resonant amplifier 502 and passes the clock signal 106 to clock distribution and timing circuitry 904. The clock distribution and timing circuitry 904 may deliver synchronized samples of the clock signal 106 to various components of the DDS 142, as illustrated in FIG. 9A. The DDS 142 further includes a digital core 910 that includes a phase accumulator 912 and a phase to amplitude converter 914, which in combination generate a digital amplitude signal having a frequency that is a fraction of the input frequency. In some examples, the phase accumulator 912 receives a frequency control word (FCW) 908, sampled on each cycle of the clock signal 106, and accumulates the FCW over time as a phase accumulation signal 920. The phase accumulator 912 comprises a delay element 916 receiving the phase accumulation signal 920, and generating a feedback signal 922. The feedback signal 922 and the FCW 908 are added by a summer 918 to generate the phase accumulation signal 920. The phase to amplitude converter 914 converts the phase accumulation signal output by the phase accumulator 912 to a digital representation of a sine wave (digital word 924). In some examples, the DDS 142 includes multiple digital cores 910 that operate in parallel, each producing a digital output word 924. This parallel implementation allows the circuitry to operate at a clock rate equal to the frequency of the clock signal 106 (e.g., 50 GHz) divided by the number of digital cores 910. The plurality of digital cores 910 in combination effectively increment an accumulator (that is the combination of the accumulators 912 in the digital cores 910) running at an aggregated clock rate equal to the frequency of the clock signal 106. The digital words 924 from the plurality of digital cores 910 are combined in a multiplexer 926 and converted to an analog output through one or more DACs 930.

According to certain examples, the DDS 142 allows fine tuning of the frequency of the output signal 114 based on the clock signal 106 and the FCW 908. As described above, the clock signal 106 can be produced having a precise and stable frequency that is controlled by the microresonator 204 and the laser control circuitry 146. However, in some instances, the frequency of the clock signal 106 may vary from the desired fixed frequency (e.g., 50 GHz) and this variation may not be constant (e.g., due to changes in temperature). Accordingly, the DDS 142 may include frequency correction circuitry to finely tune the frequency of the output signal 114 and correct for temperature-induced, or other, variations over time. Thus, the DDS 142 may include FCW correction circuitry 932 that adjusts the FCW 908 based on the actual frequency of the clock signal 106. In addition to accounting for temperature-induced shift, this approach may also relax manufacturing tolerances on the diameter of the microresonator 204, and reduce or eliminate the need for active stabilization of the frequency comb repetition rate, which may simplify design/implementation of the photonic subsystem 120.

Referring to FIG. 9B, in some examples, the FCW correction circuitry 932 measures the ratio of the frequency of a sample 934 of the clock signal 106 to a reference frequency of the input signal 112 and adjusts the FCW 908 to accomplish frequency correction. Accordingly, the DDS 142 may include a multiplexer 936 that receives the input signal 112 and the sample 934 of the clock signal 106. In some examples, the sample 934 of the clock signal 106 is a scaled version of the clock signal 106 to reduce the clock rate at which the electronics of the FCW correction circuitry 932 operate. For example, if the clock signal 106 has a nominal frequency of 50 GHz, the sample 934 may be equal to the clock signal frequency divided by 16 or 32, for example.

As described above, the FCW 908 controls the accumulation rate at which the digital core operates, and may be programmed via the digital programming interface 224, for example. Accordingly, the FCW correction circuitry 932 may receive a configuration signal 938 from the digital programming interface 224 that specifies an FCW based on the nominal frequency of the clock signal 106 and a desired frequency of the output signal 114. Based on the signals from the multiplexer 936, the FCW correction circuitry 932 adjusts the FCW 908 to account for deviations in frequency of the clock signal 106 from the nominal frequency. As described above, based on the FCW 908, the phase accumulator 912 produces the phase accumulation signal 920 that is provided to the phase to amplitude converter 914.

In the example shown in FIG. 9B, the summer 918 of FIG. 9A is implemented using an accumulation register 940 and a mixer 942. The frequency step size, or tuning resolution, of the frequency of the output signal 114 is set by the frequency of the clock signal 106 (clock rate) and the resolution (e.g., number of bits) in the accumulation register 940. In some examples, the accumulation register 940 has 26 bits. For a 50 GHz clock signal 106, this yields a frequency step size of approximately 1 kHz (50 GHz / 2²⁶). The frequency of the output signal 114 is thus set by the FCW 908 multiplied by the frequency of the clock signal 106 divided by 2^{N}, wherein N is the number of bits in the accumulation register 940. Thus, the DDS 142 can provide very fine tuning and control of the frequency of the output signal 114 by adjusting the FCW.

The phase accumulator 912 outputs the phase accumulation signal 920 as a digital ramp, which is converted into a digital sine wave by phase to amplitude conversion circuitry 942 that is part of the phase to amplitude converter 914. In some examples, to improve spurious performance of the DAC(s) 930, the phase to amplitude converter 914 includes a dynamic element matching (DEM) circuit to scramble thermometer-coded most-significant bits (MSBs) of the DAC(s) 930 to avoid situations of long runs of ones or zeros on a particular DAC current switch.

Referring to FIGS. 9A and 9B, the digital output 928 from the multiplexer 926 is provided to the one or more DACs 930 to be converted to an analog output. As described above, in some examples, the DDS 142 uses two interleaved DACs 930a, 930b, respectively covering the first and second Nyquist output ranges. In one example, the interleaved DACs 930a, 930 implement a return-to-zero approach, with their outputs combined using a mixer 948. Using the return-to-zero approach may allow the second Nyquist output range to be produced while avoiding memory effects in the digital circuitry. In some examples, the DDS 142 is implemented on a silicon germanium (SiGe) substrate, although other integration substrate materials can be used.

The analog output 950 from the DDS 142 may be filtered via the switch filter 144 to provide the output signal 114. As illustrated in FIG. 9A, in some examples, the switch filter 144 includes a bank of output filters 952. Depending on the desired frequency of the output signal 114, an individual filter can be selected from the bank of output filters 952 through complementary operation of two switches 954, 956. In some examples, the switches 954, 956 are low loss phase change material (PCM) switches. The switch filter 144 breaks the output signal 950 from the DDS 142 into multiple bands (defined by the bank of filters 952) such that harmonic spurs fall out of band, reducing the spur power.

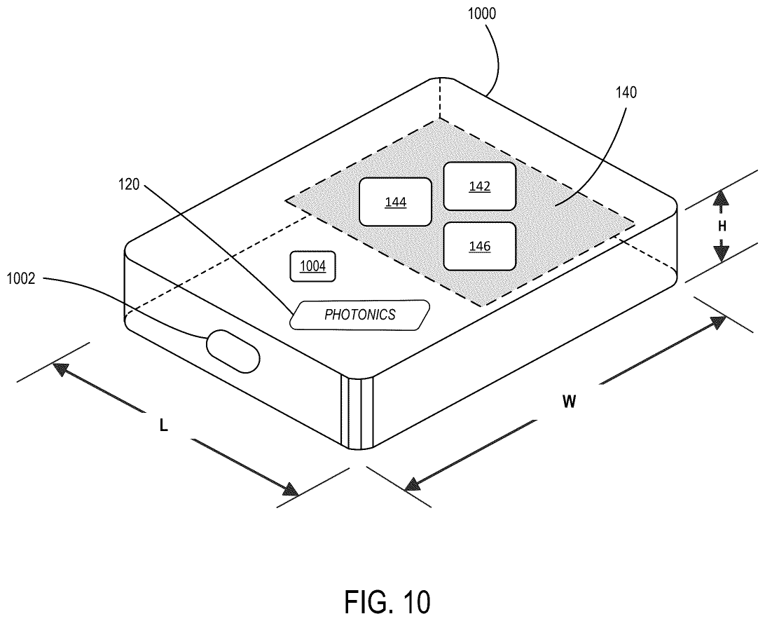

Thus, examples provide a fully configurable and programmable RF oscillator system that can produce a tunable output signal 114 over a very wide frequency range with very low phase noise. Furthermore, the RF oscillator system can be implemented in a compact package that is robust to mechanical vibration and changes in temperature. For example, referring to FIG. 10, there is illustrated an example of the RF oscillator system 100 packaged in a housing 1000. As described above, in some examples, the photonic subsystem 120 and the electronics substrate 140 having with the laser control circuitry 146, DDS 142, and switch filter 144 (electronics subsystem) implemented thereon can be packaged together within the housing 1000, as shown. In some examples, the housing is a ceramic package that comprises the photonics subsystem 120 and the electronics subsystem. The housing 1000 may include one or more connectors 1002 to allow for coupling to components of the RF oscillator system 100 that are within the housing 1000. For example, if the laser diode 102 is external to the housing 1000, the connectors 1002 may include a fiber coupler to couple the photonic subsystem 120 to the laser diode 102. The connectors 1002 may include one or more input/output (I/O) connectors to allow the input signal 112 to be coupled into the packaged system and to allow the output signal 114 to be provided to external electronics. The connectors 1002 may further include one or more digital I/O ports to allow the configuration signals 226 to be input to the digital programming interface 224, as described above, and/or to allow other control signals to be provided from external devices to components within the housing 1000. In some examples, additional circuitry 1004 is also provided within the housing 1000. For example, the additional circuitry may include some or all of the driver circuitry 130, thermal management components (e.g., one or more TECs as described above), the photodiodes 208, 210, and 212, and/or other circuitry forming part of the RF oscillator system 100.

The housing 1000 has a length, L, a width, W, and a height, H. In some examples, the height, H, is a range of 5 mm to 15 mm, the length, L, is in a range of 20 mm to 50 mm, and the width, W, is in a range of 20 mm to 50 mm. In some examples, the height, H, is in a range of 7 mm to 13 mm, the length, L, is in a range of 25 mm to 35 mm, and the width, W, is in a range of 25 mm to 30 mm. In further examples, the height, H, is in a range of 11 mm to 12 mm, the length, L, is in a range of 27 mm to 30 mm, and the width, W, is in a range of 26 mm to 29 mm. In some examples, the housing has an interior volume of less than 10 cubic centimeters. In other examples, the housing 1000 may have other dimensions than the examples provided above.

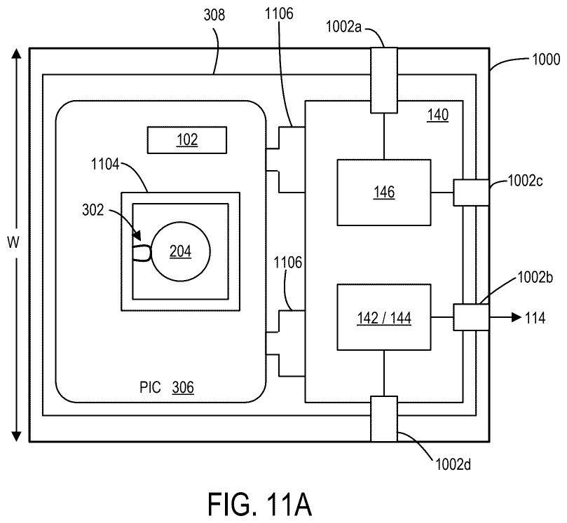

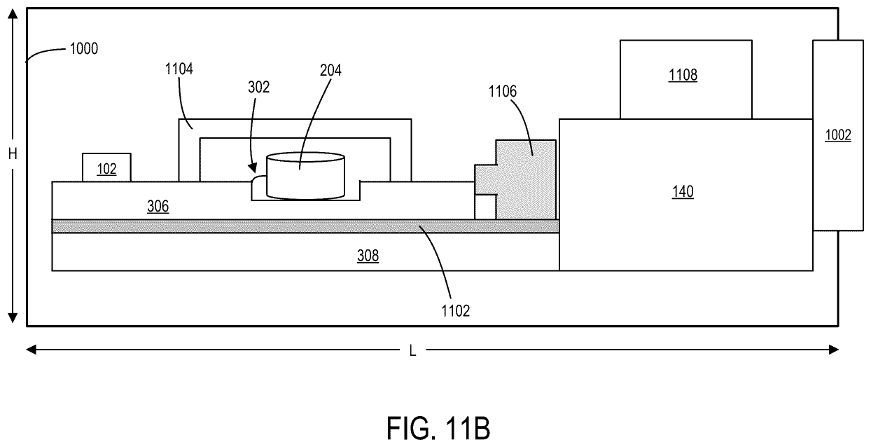

FIGS. 11A and 11B illustrate further examples of the RF oscillator system 100 packaged in the housing 1000. FIG. 11A illustrates a schematic plan (top-down) view and FIG. 11B illustrates a corresponding schematic side view. It will be appreciated that FIGS. 11A and 11B illustrate block diagram representations of the packaged RF oscillator system 100, rather than actual physical implementations, and that the various components depicted in FIGS. 11A and 11B are not drawn to scale. In the example of FIGS. 11A and 11B, the photonics subsystem 120 includes the PIC 306 described above with reference to FIG. 3, the microresonator 204, the laser diode 102, and one or more photonic wirebonds 302 acting as evanescent couplers to the microresonator 204, as described above. Thus, in this example, the laser diode 102 is packaged within the housing 1000.

As described above, the PIC 306 may include a silicon nitride substrate on which various components of the photonics subsystem are integrated, including, for example, one or more optical waveguides, directional couplers, the phase modulator 202, and/or other circuitry forming part of the photonics subsystem 120. As described above, the one or more photonic wirebonds 302 couple light between the microresonator 204 and one or more optical waveguides on the PIC 306. In some examples, photonics wirebonds 302 may also be used to couple light from the laser diode 102 to one or more optical waveguides on the PIC 306. In other examples, other coupling mechanisms (e.g., fiber couplers) can be used to couple light from the laser diode 102 to one or more optical waveguides on the PIC 306. According to certain examples, the PIC 306 is disposed on a TEC 1102. As described above, the TEC 1102 can be used to provide thermal regulation for various components of the RF oscillator system, under control of the laser control circuitry 146, for example. In some examples, a glass cap 1104 is positioned over and at least partially surrounding the microresonator 204 to prevent contamination by dust or other small particles.

As described above, one or more photodiodes 1106 (e.g., the photodiodes 208, 210, 212) couple signals from the photonics subsystem to the electronics subsystem. In some examples, the photodiodes 1106 can be integrated with the PIC 306 or the electronics substrate 140. In other examples, as shown in FIGS. 11A and 11B, the photodiodes 1106 can be separate from the electronics substrate 140. In such examples, the photodiodes 1106 and may include matching circuitry to match their electrical output(s) to appropriate components on the electronics substrate 140 (e.g., components of the laser control circuitry 146 and/or DDS 142, as described above). In some examples, the output(s) of the photodiodes 1106 can be coupled to circuitry on the electronics substrate 140 using wirebonds or other electrical connectors.

As described above, the laser control circuitry 146, the DDS 142, and the switch filter 144 can be implemented as one or more integrated circuits 1108 that are mounted on the electronics substrate 140. In some examples, the laser control circuitry 146 is implemented as a single integrated circuit and the DDS 142 and switch filter 144 are implemented (together or separately) as one or more additional integrated circuits. In some examples, the housing 1000 further contains the integration substrate 308 on which various components of the RF oscillator system 100 (e.g., the PIC 306, TEC 1102, photodiodes 1106, and optionally the electronics substrate 140), are mounted.

As described above, the packaged system can include one or more connectors 1002 that allow for transfer of signals between components within the housing 1000 and devices that are external to the housing 1000. For example, one or more first connectors 1002a can be used to couple the configuration signals 226 into the laser control circuitry 146, as described above. In some examples, the first connector(s) 1002 include a serial interface (e.g., an I2C or other digital signal interface). A second connector 1002b may allow the output signal 114 to be provided from the DDS 142 to an external device. In some examples, the second connector 1002b is a coaxial connector or other RF connector capable of handling high frequency RF signals (e.g., up to 40 GHz or higher) with low loss. A third connector 1002c (e.g., another RF connector) may be used to couple the input signal 112 to the laser control circuitry 146. In some examples, one or more fourth connectors 1002d can be used to couple additional signals to/from the DDS 142. For example, the fourth connectors 1002d may include one or more digital serial or parallel interfaces to allow programming/control signals to be provided directed to the DDS 142. In other examples, such programming/control signals may be provided to the DDS 142 via the laser control circuitry 146 (e.g., the digital programming interface) and the one or more first connectors 1002a. In some examples, the fourth connectors 1002d may include an RF connector to couple the input signal 112 to the DDS 142. In other examples, the input signal 112 can be input to the RF oscillator system 1000 via a single one of the connectors 1000 and directed to both the laser control circuitry 146 and the DDS 142 internally within the housing 1000 (e.g., using one or more waveguides, wires, or other signal carriers).

Thus, aspects and examples an RF oscillator system that can produce a highly tunable, precise output signal having very low phase noise. According to certain examples, photonic wirebonds are used to achieve evanescent coupling between photonic circuitry and a discrete crystalline optical microresonator, thereby allowing the benefits of such microresonators (e.g., extremely high Q and low-power non-linear effects for soliton generation, as described above) to be harnessed. By stabilizing the output frequency of the pump laser diode 102 to a quiet point resonance of the microresonator 204 using the PDH control loop 218, and providing RIN and APC suppression circuitry 214, 222, along with thermal management, the clock signal 106 can be generated with very low noise. Integrating the laser control circuitry 146, including the PDH control loop 218, thermal control circuitry 216, APC suppression circuitry 222, RIN suppression circuitry 214, and sideband DDS 220, into a single low-power integrated circuit allows the RF oscillator system to be implemented in a compact package, as described above. Furthermore, integration of the DDS 142 allows fast, accurate tuning of the output signal 114, to provide an agile system that can be adapted for a wide variety of applications.

### Further Examples

The following examples pertain to further aspects of the technology disclosed herein, from which numerous permutations and configurations will be apparent.

Example 1 is a radio frequency (RF) oscillator system comprising: a laser source configured to emit laser light; a housing; a crystalline microresonator disposed within the housing; a photonic integrated circuit disposed within the housing, the photonic integrated circuit including an optical waveguide network and configured to generate a clock signal based on the laser light; a photonic wirebond configured to couple the laser light between the optical waveguide network and the crystalline microresonator via evanescent coupling; laser control circuitry disposed within the housing and configured to lock a frequency of the laser light to a resonance of the microresonator to generate the clock signal; and a direct digital synthesizer disposed within the housing and configured to produce a tunable oscillator signal based on the clock signal.

Example 2 includes the RF oscillator system of Example 1, wherein the laser control circuitry comprises a Pound-Drever-Hall control loop configured to lock the frequency of the laser light to a quiet point of the microresonator.

Example 3 includes the RF oscillator system of 2, wherein the Pound-Drever-Hall control loop is configured to provide a feedback signal to adjust a DC bias current of the laser source.

Example 4 includes the RF oscillator system of any one of Examples 1-3, wherein the laser source is disposed within the housing.

Example 5 includes the RF oscillator system of any one of Examples 1-4, wherein the laser source comprises a laser diode.

Example 6 includes the RF oscillator system of any one of Examples 1-5, wherein the photonic integrated circuit comprises a phase modulator configured to modulate the laser light.

Example 7 includes the RF oscillator system of Example 6, wherein the phase modulator comprises a Mach-Zender interferometer.

Example 8 includes the RF oscillator system of any one of Examples 1-7, wherein the laser control circuitry comprises noise suppression circuitry configured to reduce phase noise of the clock signal.

Example 9 includes the RF oscillator system of Example 8, wherein the noise suppression circuitry comprises: relative intensity noise suppression circuitry configured to receive a sample of an amplitude of the laser light and to produce, based on the amplitude of the laser light, a control signal to adjust operation of the phase modulator; and amplitude to phase noise suppression circuitry configured to receive a sample of the clock signal and to produce, based on the sample of the clock signal, a feedback control signal to control one or more characteristics of a photodiode that couples the clock signal from the photonic integrated circuit to the direct digital synthesizer.

Example 10 includes the RF oscillator system of claim 1, further comprising at least one thermoelectric cooler disposed within the housing and coupled to the photonic integrated circuit, wherein the laser control circuitry includes thermal control circuitry to control the at least one thermoelectric cooler to stabilize a temperature of the photonic integrated circuit.

Example 11 includes the RF oscillator system of any one of Examples 1-10, further comprising an electronics substrate disposed within the housing; wherein the laser control circuitry comprises a single integrated circuit mounted on the electronics substrate; and wherein the direct digital synthesizer comprises one or more integrated circuits mounted on the electronics substrate.

Example 12 includes the RF oscillator system of Example 10, wherein the electronics substate is a silicon germanium substrate.

Example 13 includes the RF oscillator system of any one of Examples 1-12, wherein the photonic integrated circuit comprises a silicon nitride substrate.

Example 14 includes the RF oscillator system of any one of Examples 1-13, further comprising a switch filter coupled to an output of the direct digital synthesizer and configured to filter the tunable oscillator signal.

Example 15 includes the RF oscillator system of Example 14, wherein the switch filter comprises a bank of switchable bandpass filters.

Example 16 includes the RF oscillator system of any one of Examples 1-15, wherein the carrier frequency of the clock signal is 50 GHz ±10%, and wherein the tunable oscillator signal is tunable over a frequency range of 0 GHz to 40 GHz.

Example 17 includes the RF oscillator system of any one of Examples 1-16, wherein the direct digital synthesizer comprises a digital phase accumulator and one or more digital to analog converters configured to convert an output signal from the digital phase accumulator to the tunable oscillator signal.

Example 18 includes the RF oscillator system of any one of Examples 1-17, wherein the housing has an internal volume of less than 10 cubic centimeters.

Example 19 includes the RF oscillator system of any one of Examples 1-18, wherein the photonic wirebond comprises first and second end regions coupled to the optical waveguide network, and a loopback portion extending between the first and second end regions, wherein the loopback portion is in contact with the crystalline microresonator.

Example 20 includes the RF oscillator system of Example 19, wherein the loopback portion of the photonic wirebond has an elliptical profile.

Example 21 includes the RF oscillator system of Example 20, wherein the first and second end regions of the photonic wirebond each includes a tapered portion having a circular profile, and wherein a diameter of the circular profile substantially matches a minor diameter of the elliptical profile of the loopback portion.

Example 22 includes the RF oscillator system of Example 21, wherein the tapered portion has a length in a range of 40 μm to 250 μm.

Example 23 includes the RF oscillator system of any one of Examples 19-22, wherein the loopback portion is U-shaped.

Example 24 includes the RF oscillator system of any one of Examples 19-23, wherein the loopback portion has a radius of curvature in a range of 40 μm to 55 μm.

Example 25 includes the RF oscillator system of any one of Examples 19-24, wherein the photonic wirebond is made of a negative-tone photoresist material.

Example 26 includes the RF oscillator system of any one of Examples 19-25, wherein the crystalline microresonator includes an annular protrusion extending around a circumference of the crystalline microresonator, and wherein the photonic wirebond is positioned such that a region of the loopback portion is in contact with the annular protrusion.

Example 27 includes the RF oscillator system of any one of Examples 1-26, wherein the crystalline microresonator is made of magnesium fluoride.

Example 28 includes the RF oscillator system of Example 27, wherein the photonic wirebond is made of SU-8.

Example 29 is a radio frequency (RF) oscillator system comprising: a housing; a photonic subsystem disposed within the housing, the photonic subsystem including a laser diode, a crystalline microresonator, and photonic circuitry configured to produce a clock signal based on light emitted by the laser diode; laser control circuitry disposed within the housing, the laser control circuitry including a Pound-Drever-Hall control loop configured to lock a frequency of the light emitted by the laser diode to a quiet point of the microresonator; and a direct digital synthesizer disposed within the housing and configured to produce an oscillator output signal based on the clock signal, a frequency of the oscillator output signal being tunable over an output frequency range.

Example 30 includes the RF oscillator system of Example 29, wherein the photonic circuitry comprises: a phase modulator configured to modulate the light emitted by the laser diode; an optical waveguide arranged to guide the light emitted by the laser diode; and a photonic wirebond configured to couple the light between the optical waveguide and the crystalline microresonator via evanescent coupling.

Example 31 includes the RF oscillator system of claim 14, wherein the crystalline microresonator includes an annular protrusion extending around a circumference of the crystalline microresonator, and wherein the photonic wirebond comprises first and second end portions coupled to the optical waveguide and a loopback portion extending between the first and second end portions, the photonic wirebond being positioned such that a region of the loopback portion is in contact with the annular protrusion of the crystalline microresonator.

Example 32 includes the RF oscillator system of Example 31, wherein the loopback portion of the photonic wirebond has an elliptical profile.

Example 33 includes the RF oscillator system of Example 32, wherein the first and second end regions of the photonic wirebond each includes a tapered portion having a circular profile, and wherein a diameter of the circular profile substantially matches a minor diameter of the elliptical profile of the loopback portion.

Example 34 includes the RF oscillator system of Example 33, wherein the tapered portion has a length in a range of 40 μm to 250 μm.

Example 35 includes the RF oscillator system of any one of Examples 31-34, wherein the loopback portion is U-shaped.

Example 36 includes the RF oscillator system of any one of Examples 21-35, wherein the loopback portion has a radius of curvature in a range of 40 μm to 55 μm.

Example 37 includes the RF oscillator system of any one of Examples 30-37, wherein the photonic wirebond is made of a negative-tone photoresist material.

Example 38 includes the RF oscillator system of Example 37, wherein the photonic wirebond is made of SU-8.

Example 39 includes the RF oscillator system of any one of Examples 30-38, wherein the crystalline microresonator is made of magnesium fluoride.

Example 40 includes the RF oscillator system of any one of Examples 29-39, further comprising at least one thermal regulation component disposed within the housing and coupled to one or more components of the photonic subsystem.

Example 41 includes the RF oscillator system of Example 40, wherein the laser control circuitry comprises thermal control circuitry configured to control one or more operating parameters of the at least one thermal regulation component.

Example 42 includes the RF oscillator system of one of Examples 40 or 41, wherein the at least one thermal regulation component comprises at least one thermoelectric cooler.

Example 43 includes the RF oscillator system of any one of Examples 29-42, wherein the laser control circuitry comprises: an input port; ; and a sideband direct digital synthesizer (DDS) coupled to the first input port and configured to produce a modulation signal and a reference signal based on an input signal received via the input port, the modulation signal and the reference signal having a same frequency; wherein the Pound-Drever-Hall control loop is coupled to the sideband DDS and configured to control a DC bias current for the laser diode based at least in part on the reference signal to lock the frequency of the light emitted by the laser diode to the quiet point of the microresonator.

Example 44 includes the RF oscillator system of any one of Examples 29-43, wherein the housing has an internal volume of less than 10 cubic centimeters.

Example 45 includes the RF oscillator system of any one of Examples 29-44, wherein the photonic circuitry comprises a phase modulator configured to modulate the light emitted by the laser diode to produce the clock signal.

Example 46 includes the RF oscillator system of Example 45, wherein the phase modulator comprises a Mach-Zender interferometer.

Example 47 includes the RF oscillator system of any one of Examples 29-46, wherein the laser control circuitry comprises noise suppression circuitry configured to reduce phase noise of the clock signal.

Example 48 includes the RF oscillator system of Example 47, wherein the noise suppression circuitry comprises: relative intensity noise suppression circuitry configured to receive a sample of an amplitude of the light emitted by the laser diode and to produce, based on the amplitude of the light emitted by the laser diode, a control signal to adjust operation of the phase modulator; and amplitude to phase noise suppression circuitry configured to receive a sample of the clock signal and to produce, based on the second sample of the clock signal, a feedback control signal to control one or more characteristics of a photodiode that couples the clock signal from the photonic integrated circuit to the direct digital synthesizer.

Example 49 is an RF oscillator system comprising: a housing having an internal volume of less than 50 cubic centimeters; a laser diode disposed within the housing and configured to emit laser light; a photonic integrated circuit (PIC) disposed within the housing, the PIC including an optical waveguide network and configured to generate a clock signal based on the laser light; a crystalline microresonator disposed within the housing; a photonic wirebond configured to couple the laser light between the optical waveguide network and the crystalline microresonator via evanescent coupling; laser control circuitry disposed within the housing and configured to lock a frequency of the light emitted by the laser diode to a quiet point of the microresonator; and a direct digital synthesizer disposed within the housing and configured to produce a tunable oscillator output signal based on the clock signal.

Example 50 includes the RF oscillator system of Example 49, wherein the crystalline microresonator is made of magnesium fluoride, wherein the frequency of the light emitted by the laser diode is 50 GHz ±10%, and wherein the tunable oscillator output signal is tunable over a frequency range of 0-40 GHz.

Example 51 includes the RF oscillator system of one of Examples 49 or 50, wherein the laser control circuitry comprises a Pound-Drever-Hall control loop configured to control a DC bias current of the laser diode to lock the frequency of the light emitted by the laser diode to the quiet point of the microresonator.

Example 52 includes the RF oscillator system of any one of Examples 49-51, wherein the photonic wirebond comprises first and second end regions coupled to the optical waveguide network, and a loopback portion extending between the first and second end regions.

Example 53 includes the RF oscillator system of Example 52, wherein the loopback portion has an elliptical profile, and wherein the first and second end regions have a circular profile and are tapered, having a first diameter at coupling points to the optical waveguide network and a second diameter at respective junctions with the loopback portion, wherein the second diameter is smaller than the first diameter.

Example 54 includes the RF oscillator system of one of Examples 52 or 53, wherein the crystalline microresonator has a circular cross-section and includes an annular protrusion extending around a circumference of the crystalline microresonator, and wherein the photonic wirebond is arranged such that the loopback portion contacts the annular protrusion of the crystalline microresonator.

The terms and expressions which have been employed herein are used as terms of description and not of limitation, and there is no intention, in the use of such terms and expressions, of excluding any equivalents of the features shown and described (or portions thereof), and it is recognized that various modifications are possible within the scope of the claims. Accordingly, the claims are intended to cover all such equivalents. Various features, aspects, and examples have been described herein. The features, aspects, and examples are susceptible to combination with one another as well as to variation and modification, as will be appreciated in light of this disclosure. The present disclosure should, therefore, be considered to encompass such combinations, variations, and modifications. It is intended that the scope of the present disclosure be limited not by this detailed description, but rather by the claims appended hereto. Future filed applications claiming priority to this application may claim the disclosed subject matter in a different manner and may generally include any set of one or more elements as variously disclosed or otherwise demonstrated herein.

What is claimed is:

1. A radio frequency (RF) oscillator system comprising:
a laser source configured to emit laser light;
a housing;
a crystalline microresonator disposed within the housing;
a photonic integrated circuit disposed within the housing, the photonic integrated circuit including an optical waveguide network and configured to generate a clock signal based on the laser light;
a photonic wirebond configured to couple the laser light between the optical waveguide network and the crystalline microresonator via evanescent coupling;
laser control circuitry disposed within the housing and configured to lock a frequency of the laser light to a resonance of the microresonator to generate the clock signal; and
a direct digital synthesizer disposed within the housing and configured to produce a tunable oscillator signal based on the clock signal.

2. The RF oscillator system of claim 1, wherein the laser control circuitry comprises a Pound-Drever-Hall control loop configured to lock the frequency of the laser light to a quiet point of the microresonator.

3. The RF oscillator system of claim 1, wherein the laser source is disposed within the housing.

4. The RF oscillator system of claim 1, wherein the photonic integrated circuit comprises a phase modulator configured to modulate the laser light.

5. The RF oscillator system of claim 4, wherein the laser control circuitry comprises noise suppression circuitry configured to reduce phase noise of the clock signal.

6. The RF oscillator system of claim 5, wherein the noise suppression circuitry comprises:
relative intensity noise suppression circuitry configured to receive a sample of an amplitude of the laser light and to produce, based on the amplitude of the light, a control signal to adjust operation of the phase modulator; and
amplitude to phase noise suppression circuitry configured to receive a sample of the clock signal and to produce, based on the sample of the clock signal, a feedback control signal to control one or more characteristics of a photodiode that couples the clock signal from the photonic integrated circuit to the direct digital synthesizer.

7. The RF oscillator system of claim 1, further comprising at least one thermoelectric cooler disposed within the housing and coupled to the photonic integrated circuit;
wherein the laser control circuitry includes thermal control circuitry to control the at least one thermoelectric cooler to stabilize a temperature of the photonic integrated circuit.

8. The RF oscillator system of claim 1, further comprising an electronics substrate disposed within the housing;
wherein the laser control circuitry comprises a single integrated circuit mounted on the electronics substrate; and
wherein the direct digital synthesizer comprises one or more integrated circuits mounted on the electronics substrate.

9. The RF oscillator system of claim 1, further comprising a switch filter coupled to an output of the direct digital synthesizer and configured to filter the tunable oscillator signal.

10. The RF oscillator system of claim 1, wherein the carrier frequency of the clock signal is 50 GHz±10%; and
wherein the tunable oscillator signal is tunable over a frequency range of 0 GHz to 40 GHz.

11. The RF oscillator system of claim 1, wherein the housing has an internal volume of less than 10 cubic centimeters.

12. The RF oscillator system of claim 1, wherein the photonic wirebond comprises first and second end regions coupled to the optical waveguide network, and a loopback portion extending between the first and second end regions, wherein the loopback portion is in contact with the crystalline microresonator.

13. A radio frequency (RF) oscillator system comprising:
a housing;
a photonic subsystem disposed within the housing, the photonic subsystem including a laser diode, a crystalline microresonator, and photonic circuitry configured to produce a clock signal based on light emitted by the laser diode;
laser control circuitry disposed within the housing, the laser control circuitry including a Pound-Drever-Hall control loop configured to lock a frequency of the light emitted by the laser diode to a quiet point of the microresonator; and
a direct digital synthesizer disposed within the housing and configured to produce an oscillator output signal based on the clock signal, a frequency of the oscillator output signal being tunable over an output frequency range.

14. The RF oscillator system of claim 13, wherein the photonic circuitry comprises:
a phase modulator configured to modulate the light emitted by the laser diode;
an optical waveguide arranged to guide the light emitted by the laser diode; and
a photonic wirebond configured to couple the light between the optical waveguide and the crystalline microresonator via evanescent coupling.

15. The RF oscillator system of claim 14, wherein the crystalline microresonator includes an annular protrusion extending around a circumference of the crystalline microresonator; and
wherein the photonic wirebond comprises first and second end portions coupled to the optical waveguide and a loopback portion extending between the first and second end portions, the photonic wirebond being positioned such that a region of the loopback portion is in contact with the annular protrusion of the crystalline microresonator.

16. The RF oscillator system of claim 13, further comprising at least one thermal regulation component disposed within the housing and coupled to one or more components of the photonic subsystem.

17. The RF oscillator system of claim 13, wherein the laser control circuitry comprises:
a first input port; and
a sideband direct digital synthesizer (DDS) coupled to the first input port and configured to produce a modulation signal and a reference signal based on an input signal received via the first input port, the modulation signal and the reference signal having a same frequency;
wherein the Pound-Drever-Hall control loop is coupled to the sideband DDS, and configured to control a DC bias current signal for the laser diode based at least in part on the reference signal to lock the frequency of the light emitted by the laser diode to the quiet point of the microresonator.

18. The RF oscillator system of claim 13, wherein the housing has an internal volume of less than 10 cubic centimeters.

19. An RF oscillator system comprising:
a housing having an internal volume of less than 50 cubic centimeters;
a laser diode disposed within the housing and configured to emit laser light;
a photonic integrated circuit (PIC) disposed within the housing, the PIC including an optical waveguide network and configured to generate a clock signal based on the laser light;
a crystalline microresonator disposed within the housing;
a photonic wirebond configured to couple the laser light between the optical waveguide network and the crystalline microresonator via evanescent coupling;
laser control circuitry disposed within the housing and configured to lock a frequency of the light emitted by the laser diode to a quiet point of the microresonator, and
a direct digital synthesizer disposed within the housing and configured to produce a tunable oscillator output signal based on the clock signal.

20. The RF oscillator system of claim 19, wherein the crystalline microresonator is made of magnesium fluoride, wherein the frequency of the light emitted by the laser diode is 50 GHz±10%, and wherein the tunable oscillator output signal is tunable over a frequency range of 0-40 GHz.
